(19) United States
(12) Patent Application Publication
(10) Pub. No.: US 2008/0258815 A1
(43) Pub. Date: Oct. 23, 2008

(54) HIGH FREQUENCY POWER AMPLIFIER AND WIRELESS PORTABLE TERMINAL USING THE SAME

(75) Inventors: Kazuhide ABE, Kawasaki-Shi (JP); Tadahiro Sasaki, Tokyo (JP); Kazuhiko Itaya, Yokohama-Shi (JP); Hideyuki Funaki, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/871,451

(22) Filed: Oct. 12, 2007

(30) Foreign Application Priority Data
Mar. 29, 2007 (JP) 2007-086955

(51) Int. Cl. H03F 3/16

(52) U.S. Cl. 330/277

(57) ABSTRACT

An object is to provide a high frequency power amplifier in which lowering of output power during operation is prevented, influence of thermal noise is suppressed, high frequency operation is stable, and long-term reliability is ensured. The high frequency power amplifier includes a plurality of transistors having gate electrodes, source regions and drain regions, the gate electrodes, source regions and drain regions being respectively connected in common, and a plurality of acoustic reflection layers being buried in portions of the semiconductor substrate, the portions being located between adjacent transistors, the acoustic reflection layers being disposed in a direction which is oblique to a length direction of the gate electrode.

### CROSS-REFERENCE TO RELATED APPLICATION

This application is based upon and claims the benefit of priority from prior Japanese Patent Application No. 2007-86955 filed on Mar. 29, 2007 in Japan, the entire contents of which are incorporated herein by reference.

### BACKGROUND OF THE INVENTION

1. Field of the Invention

The present invention relates to a high frequency power amplifier and a wireless portable terminal using the high frequency power amplifier.

2. Related Art

High frequency power amplifier conventionally uses a transistor formed of a compound semiconductor such as gallium arsenide (GaAs) at the final stage of a transmitter block in a wireless communication system. As the CMOS process advances, however, an endeavor has been continued to implement not only a digital circuit in a baseband block by CMOS, but also a high frequency analog circuit in a front-end transceiver by CMOS. As compared with the compound semiconductor process or the Si—Ge process, the standard CMOS process has a possibility that all transmitter and receiver circuits can be implemented on a single silicon chip in the future. The single chip transceiver is already available in the market in part. The merit of the CMOS process is the reduced cost per unit area at the time of mass production.

If a high frequency power amplifier consists of MOS field effect transistors, since MOS transistors can be laid out with very high density on the Si substrate, the influence of heat generation is more serious as compared with the conventional art. Especially when the signal is linearly amplified with class A or class B operation, the power consumed within transistors increases and the amount of heat generated per unit time also increases.

If transistors are laid out in a limited area at high density by making use of the minimum design rules for the advanced fine process, the heat generation raises the channel temperature, which results in lowering of output power of transistors, increase of thermal noise, and remarkable damage on long-term reliability.

When a high frequency power amplifier consists of CMOS transistors, it is typical to employ a so-called multi-finger layout configuration. Since the breakdown voltage of a MOS transistor is relatively low, large current flow is necessary through channels of the MOS transistor to generate a high-power output signal. For letting a large current flow through a MOS transistor under a constant voltage, a broader channel width W is necessary, because whole carriers such as electrons and holes have to pass through the limited width of the channel.

Since gate electrodes of MOS transistors consist of polysilicon, the resistivity of the gate electrodes is higher than that of metal wires such as aluminum (Al) or copper (Cu) by two or three digits. During amplification of a high frequency signal, the MOS capacitor formed of a gate insulation film is alternatively charged and discharged. However, the charging and discharging current for the gate capacitors must be conducted via a high resistance gate electrode. If the gate electrode consists of a single and long polysilicon, it takes time to charge and discharge the gate capacitor, and it is unsuitable for high frequency amplification. Therefore, it is common to employ a design configuration in which a large transistor is divided into multiple small transistors which are connected in parallel. In such a configuration, each piece of the gate electrode is called gate finger. The whole configuration in which multiple transistors are connected in parallel is called multi-finger configuration.

For power amplifier applications, the MOS transistor designed with the multi-finger configuration is typically formed on, for example, a p-type Si substrate with a source-drain region of n-type conduction. The gate electrode is divided into multiple fingers, and the multiple fingers are arranged in a comb form. The drain region and the source region are shared by adjacent MOS transistors to reduce the layout area.

For the n-type MOS transistor designed with the multi-finger configuration, current-voltage (Ids-Vds) curves are measured and compared with those simulated. In a transistor with a small channel width, measured curves agree well with simulated curves. On the other hand, in a transistor with a larger channel width, differences between them become gradually larger. The larger channel width of the transistor results in the larger discrepancies between the measurement and the simulation.

The discrepancy between measurement and simulation for a transistor with a large channel width can be explained by assuming the large amount of heat generation caused by the large current flow, and consequently by the temperature rise of the transistor. The temperature rise lowers mobility of electrons which are conducted through the channel of the N-type transistor. Such a phenomenon is called a self-heating effect.

Electrons are the major carriers of an N-type transistor, and their mobility becomes smaller as the temperature rises.

$$μ = {{μ}_{0} ( \frac{T}{{T}_{0}} )}^{{μ}_{TE}}$$

Here, μ is the mobility, μ₀ is the mobility at a reference temperature, T is the temperature, T₀ is the reference temperature, and μ_{TE} is a mobility temperature index (approximately −1.5).

An effect of thermal coupling between adjacent transistors is described in a literature (Oleg Semenov et al., IEEE Transactions on Device and Materials Reliability, Vol. 6, No. 1, 2006, pp. 17-27). A simulation result concerning temperature distribution obtained for two MOS transistors laid out so as to be adjacent to each other is shown in FIG. 8 in the literature just cited. According to the authors, there is strong overlap in the temperature distribution in the case where the space between the adjacent gate fingers is as small as the minimum design rule spacing of the process. It is indicated that heat generated by one of the transistors affects the temperature rise of the other transistors.

In addition, it is predicted that a larger space between gate fingers of 2.4 μm weakens the overlap of temperature distribution and lowers the peak temperature as well at the heat source. However, the effect of temperature lowering improved by broadening of the space between fingers is insufficient to ensure the reliability.

The above-described problems are summarized as below. In a MOS transistor used for power amplification, the number of fingers increases as the channel width W becomes large. The MOS transistor designed with a multi-finger configuration and fabricated with an advanced fine process, the channel temperature remarkably rises due to the self-heat effect and thermal interference between gate fingers. As the result, the output power is lowered. In addition, the rise of the channel temperature increases thermal noise superposed on the output signal, accelerates the degradation of transistors, and impairs the long-term reliability. Although increasing the space between fingers is anticipated to exhibit a little effect to prevent the temperature rise, the effect is not sufficient to avoid the above drawbacks.

### SUMMARY OF THE INVENTION

The present invention has been made in view of these circumstances, and an object thereof is to provide a high frequency power amplifier, in which output power lowering is prevented during the operation, generation of thermal noise is small, high frequency operation is stable, and long-term reliability is ensured, and therefore, which is suitable for variety of high frequency applications, such as wireless communication systems.

A high frequency power amplifier according to a first aspect of the present invention includes: a plurality of transistors formed in a semiconductor substrate and having gate electrodes, source regions and drain regions, the gate electrodes, source regions and drain regions being respectively connected in common; and a plurality of acoustic reflection layers being buried in portions of the semiconductor substrate, the portions being located between adjacent transistors, the acoustic reflection layers being disposed in a direction which is oblique to a length direction of the gate electrodes.

A wireless portable terminal according to a second aspect of the present invention includes: the high frequency power amplifier according to the first aspect in a transmission circuit.

### BRIEF DESCRIPTION OF THE DRAWINGS

FIGS. 1A and 1B are diagrams showing a MOS transistor according to a first embodiment;

FIGS. 2A and 2B are diagrams showing a MOS transistor according to the first embodiment;

FIGS. 3A and 3B are diagrams showing a MOS transistor according to the first embodiment;

FIGS. 4A and 4B are diagrams showing a MOS transistor according to the first embodiment;

FIG. 5 is a diagram showing a three-dimensional layout of MOS transistors according to the first embodiment;

FIG. 6 shows an equivalent circuit of a MOS transistor according to the first embodiment;

FIG. 7 is a schematic diagram showing scattering of electrons conducted by a crystal lattice and a generation mechanism of longitudinal wave phonons;

FIGS. 8A and 8B are diagrams showing a direction in which thermal energy flows and a direction in which a current flows, in a MOS transistor;

FIGS. 9A and 9B are diagrams showing a MOS transistor according to a second embodiment;

FIG. 10 is a diagram showing a three-dimensional layout of MOS transistors according to the second embodiment; and

FIG. 11 is a block diagram of a transmission circuit in a wireless portable terminal according to a third embodiment.

### DESCRIPTION OF THE INVENTION

Hereafter, embodiments of the present invention will be described with reference to the drawings.

### First Embodiment

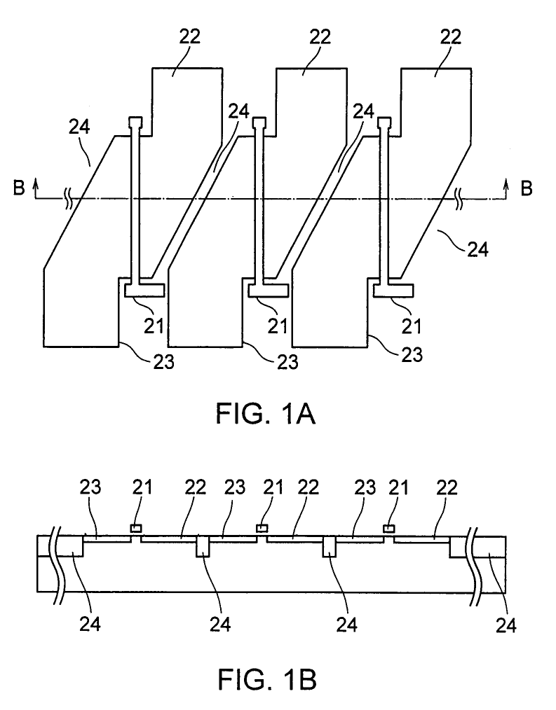

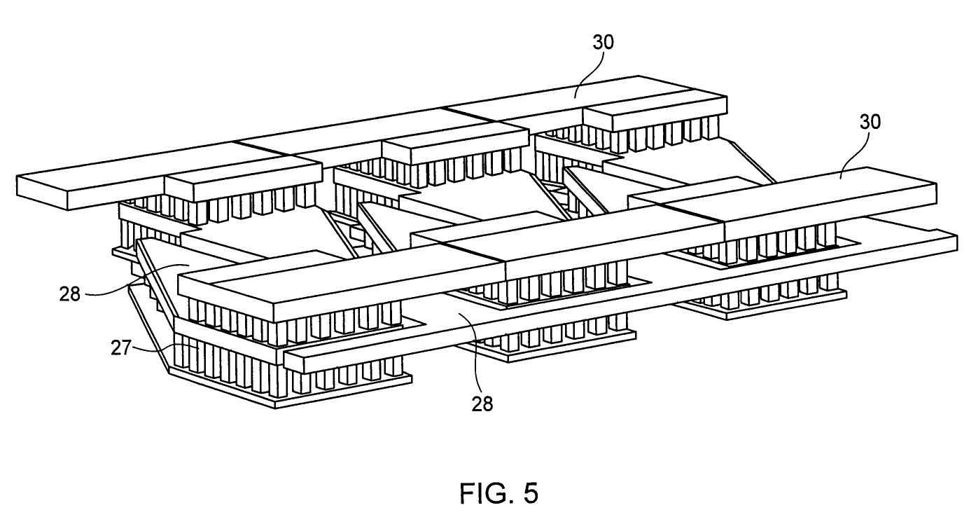

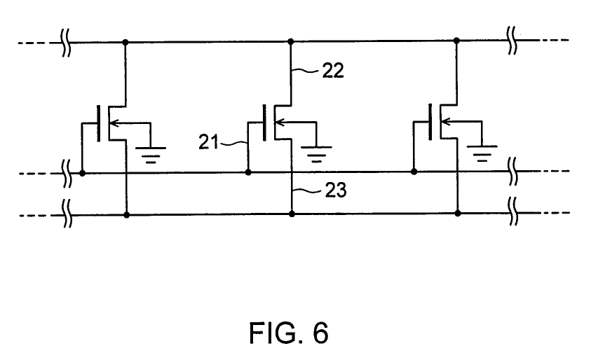

FIGS. 1A to 4B show a layout of a MOS transistor for high frequency power amplifier according to a first embodiment of the present invention. FIGS. 1A, 2A, 3A and 4A are plan views, and FIGS. 1B, 2B, 3B and 4B are sectional views obtained by cutting along cutting lines B-B in FIGS. 1A, 2A, 3A and 4A, respectively. FIG. 5 shows a three-dimensional layout of MOS transistors according to the present embodiment. FIG. 6 is an equivalent circuit of a transistor shown in FIGS. 1A-4B. A MOS transistor with a large channel width shown in FIGS. 1A, 1B and 6 is divided into three small transistors and connecting three transistors in parallel so as to flow a large drain current. In this example, the transistor divided into three small transistors has been shown for brevity. For a MOS transistor with a larger channel width W, however, it is desirable to further increase the number of small transistors connected in parallel.

The N-type MOS transistor is formed on a silicon substrate which exhibits a P-type conductivity. As shown in FIGS. 1A and 1B, each MOS transistor includes a gate 21, a drain 22 and a source 23 formed in an active area. A buried acoustic reflection layer 24 of SiO₂ is formed between adjacent transistors. The buried acoustic reflection layer 24 is buried in the silicon substrate. The depth of the buried acoustic reflection layer 24 is approximately 250 nm from the surface of the silicon substrate. The materials of the buried acoustic reflection layer can be SiN or Al₂O₃ besides SiO₂.

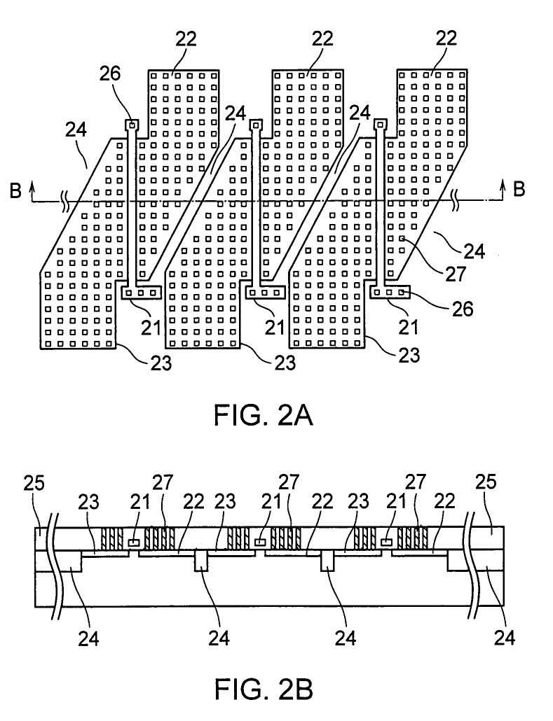

After the transistors are formed, they are covered by an insulation interlayer 25 as shown in FIGS. 2A and 2B. Contact holes are opened and wiring metal is buried, and planarization is carried out by a chemical mechanical polishing process. Contact holes 26 are opened on the gate electrode 21 for an electrical connection to the gate electrode. Contact holes 27 are opened into the drain region 22 and the source region 23 to form electrical contacts from respective regions.

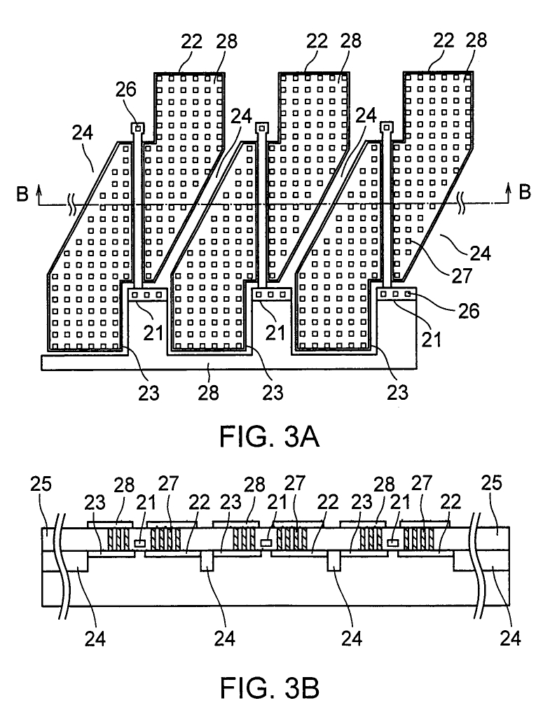

As shown in FIGS. 3A and 3B, the first wiring layer 28 is deposited on the interlayer insulation film 25. It is desirable to form the first wiring layer 28 of highly conductive metal such as aluminum (Al) or copper (Cu). In the present embodiment, the first wiring layer 28 is not only used as lead electrodes from the drain regions and the source regions formed on the silicon substrate, but also used as lead wiring of the gate electrode 21 and also used as inter-connects of a plurality of gate electrodes.

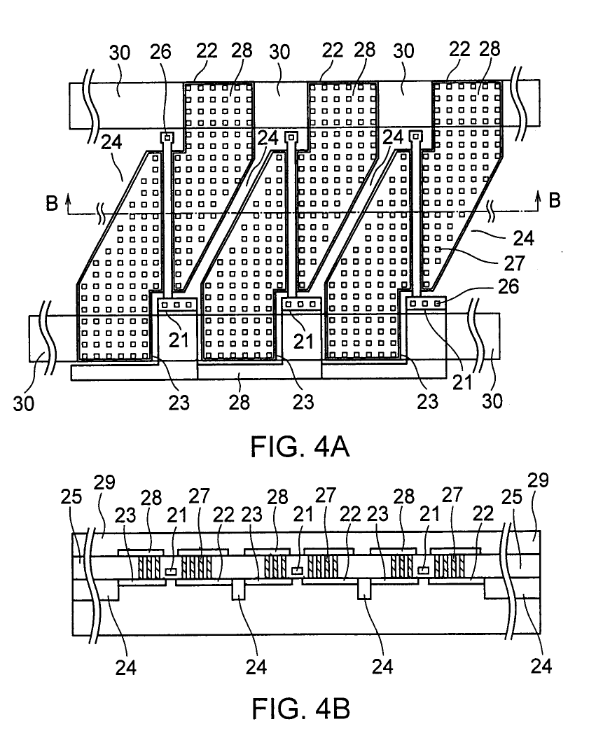

As shown in FIGS. 4A and 4B, an insulation interlayer 29 is further formed, and the second wiring layer 30 is formed. The second wiring layer 30 is also used as lead wires from the drain regions and the source regions of a plurality of transistors. FIG. 5 is a three-dimensional layout view in the present embodiment constructed by the process shown in FIGS. 1A to 4B in this order.

In order to describe the effect of the present embodiment with a novel configuration of the MOS transistor, the heat generation and heat conduction mechanism in the improved MOS transistor is described below.

In the MOS transistor, an inversion layer is formed at the channel by application of the gate voltage, and carriers can flow through the inversion layer. As for the carrier in the inversion layer of silicon, three types of scattering factors are known: impurity scattering, lattice scattering and surface scattering. As the temperature rises, the lattice scattering (phonon scattering) becomes dominant among them (see, for example, Y. Cheng et al., Semicond. Sci. Technol. 12 (1997) 1349-1354). When an electron collides with a crystal lattice and loses energy, phonon energy is excited in the crystal lattice. Microscopically, this is the origin of heat generation in the MOS transistor. It is known that the electrons are scattered by the longitudinal mode of phonons but not scattered by transverse phonons. This indicates that the longitudinal mode of phonons gains energy when electrons are scattered by the crystal lattice and lose their energy.

Energy of lattice vibration generated by the collision propagates in the silicon crystal. If the crystal boundary, impurities, dislocation and interaction between phonons are negligible, thermal energy propagates in the crystal extremely fast with a group velocity of phonons, i.e., the acoustic velocity. As a matter of fact, however, energy of the lattice vibration is converted to different modes by inharmonic scattering and eventually changed to thermal vibration with the random direction (under thermal equilibrium).

Measurement results concerning the dependence of the thermal conductivity in silicon single crystal upon the temperature are described, and its conduction mechanism is discussed in a literature (C. J. Glassbrenner and G. A. Slack, Phys. Rev. 134 (1964) A1058-A1069). The authors of this literature reveals experimentally that heat is conducted in silicon single crystal mainly by phonons, whereas heat is conducted in metal mainly by electrons. It is also indicated that the dominant factor of the heat conduction depends on the temperature, phonon scattering caused by the crystal boundary is dominant at low temperatures of 10 K or below, phonon scattering caused by an isotope contained in the crystal is dominant in the temperature range of approximately 10 K to 100 K, and umclapp scattering is dominant at temperatures of 100 K or above. Therefore, heat conduction in the silicon crystal at temperatures near the room temperature (300 K) is dominantly limited by the umclapp scattering.

The process of phonon-phonon scattering, in which two phonons collide with each other and one new phonon is generated, can be classified into two types, a normal process and an umclapp process. In the normal process, a wave vector of generated phonons comes in the inside of the Brillouin zone, and there is no substantial change in the direction of energy propagation between before and after the collision. Therefore, there is also little change in the direction and velocity of heat flow. In the umclapp process in contrast, the wave vector of generated phonons goes to the outside of the Brillouin zone, and consequently the direction of energy propagation is inverted. If such umclapp scattering frequently occurs, then the average velocity of thermal energy propagation caused by the whole phonons becomes low and the thermal conductivity becomes low.

The probability of occurrence of umclapp scattering depends upon the temperature. As a necessary condition for occurrence of the umclapp scattering, the magnitude of the wave vector of phonons before the collision must be at least greater than half of the first Brillouin zone. The probability of phonons having such a wave number is higher for higher temperature. That is the reason why the probability of the umclapp scattering depends upon the temperature. According to the theory of thermal conductivity, the umclapp scattering occurs frequently, when the temperature is higher than Θ/2, where Θ denotes the Debye temperature. Since the Debye temperature of silicon single crystal is Θ=640 K, the room temperature (300 K) is below half of the Debye temperature. In the silicon crystal, therefore, the probability of existence of phonons having energy capable of the umclapp scattering is relatively low at the room temperature. As a result, the thermal conductivity of silicon is high (168 W/mK) compared with other semiconductor materials.

With a rough approximation, the thermal conductivity is given by

$$κ = \frac{1}{3} λ vC$$

where, κ is thermal conductivity, v is a group velocity of phonons, C is a specific heat per unit volume, and λ is a mean free path between collides at which phonons exchange energy.

Using K=1.68 W/cmK as the thermal conductivity, C=1.6 J/cm³K as the specific heat per unit volume, and v=6.4×10⁵ cm/sec as the mean acoustic velocity for silicon single crystal, the above equation gives the mean free path in phonon scattering of 0.05 μm. This value is approximately in the range of half to one several-th of the minimum design rules used in the typical CMOS process at the present technology level.

On the other hand, measured data concerning the dependence of the relaxation time of phonon scattering upon the temperature within the silicon single crystal are reported in a literature (Y. V. Ilisavski, V. M. Sternin, Sov. Phys. Solid State 27 (1985) 236 through G. G. Sahasrabudhe and S. D. Lambade, J. Phys. Chem. Solid. 60 (1999) 773-785). These data are measured acoustically, and they correspond to values obtained by averaging with respect to phonons excited at that temperature. According to the literature, τ=2.2×10⁻¹⁰ sec is obtained at the room temperature with respect to a longitudinal wave traveling in the [100] direction of Si (see FIG. 1 in the literature). On the other hand, there is the following relation between the relaxation time τ of the phonon scattering and the mean free path λ.

λ=τV

Here, v is the acoustic velocity. As the velocity of sound propagating through the silicon crystal in the [100] direction, v=8.43×10⁵ cm/sec is known. Estimating the mean free path of phonons from this relation, λ=1.9 μm is obtained. This corresponds to several times to ten times as large as the minimum design rules in the CMOS process.

The authors of the literature pointed out, in the explanation of such a difference in the values of the mean free path estimated by different methods, that the measured thermal conductivity or specific heat typically contains the influence of the transverse wave phonons, and that contribution of the transverse wave phonons is rather large.

On the other hand, the result obtained by the acoustical measurement using the longitudinal wave shown by Y. V. Ilisavski et al. is relaxation time concerning the scattering of acoustic longitudinal wave phonons. If their explanation is correct, the longitudinal acoustic phonons are hard to be scattered in the silicon crystal as compared with the transverse acoustic phonons.

According to the authors of the literature, the relaxation times for longitudinal waves in the [100] direction and [110] direction are measured and compared, and it is indicated that the relaxation time in the [100] direction is longer. This means that the longitudinal acoustic phonons which propagate in the [100] direction are hard to be scattered as compared with longitudinal acoustic phonons which propagate in other directions as well.

It is known that when electrons are scattered by phonons, the electrons are scattered only by the longitudinal wave mode of phonons and not scattered by transverse wave phonons.

In conclusion, longitudinal wave phonons generated by collision between electrons and crystal lattices in the channel (inversion layer) of the CMOS transistor can travel a distance in the range of several times to ten times as long as the minimum design rule dimension of the process, as an acoustic lattice wave without being scattered. Based on the findings heretofore described, the present embodiment has a configuration which efficiently lets thermal energy spread from the transistor immediately after it is generated in the channel, by utilizing the fact that the thermal energy propagates as longitudinal wave acoustic phonons.

Specifically, it is possible to prevent acoustic phonons generated in the channel of one of transistors from arriving at the other of the transistors, and also possible to suppress thermal interference between the transistors, by burying an acoustic reflection layer, which has acoustic impedance different from that of a silicon substrate, between adjacent gate fingers.

For example, in the present embodiment, SiO₂ is used as a material which constitutes the acoustic reflection layer. It is known that the density of SiO₂ is 2.2 g/cm³ and the acoustic velocity of the longitudinal wave is 5.7×10³ m/sec. Acoustic impedance estimated from these values is ZsiO₂=12.5×10⁶ kg/m² sec. On the other hand, the density of silicon single crystal is 2.33 g/cm³ and the acoustic velocity of the longitudinal wave which propagates in the [100] direction is 8.43×10³ m/sec. Acoustic impedance estimated from these values is Zsi=19.6×10⁶ kg/m²sec. Acoustic wave is reflected at the interface because of the difference in acoustic impedance.

SiO₂ has a thermal conductivity of 1 W/mK, whereas Si has a thermal conductivity of 168 W/mK. Therefore, due to the difference of thermal conductivity, thermal energy, which has propagated in the silicon crystal from the heat source to the interface between the silicon crystal and SiO₂, is hard to penetrate into SiO₂ from the interface.

In the transistor according to the present embodiment, its gate electrode is disposed in parallel to the [100] direction of the silicon crystal. The [100] direction is the direction in which electrons are accelerated from the source toward the drain by an electric field, and the direction in which longitudinal wave phonons generated by collision between accelerated electrons and the crystal lattice propagate, and also the direction in which acoustic phonons are hard to be scattered, and consequently the direction in which the thermal energy generated by the MOS transistor can spread outside more rapidly. In the present embodiment, the gate electrode is disposed in parallel to the [100] orientation of the silicon crystal. The gate electrode may be disposed in parallel to the [010] orientation, [001] orientation, [−100] orientation, [0−10] orientation or [00−1] orientation. The [010] orientation, the [001] orientation, the [−100] orientation, the [0−10] orientation and the [00−1] orientation are orientations equivalent to the [100] orientation, and they are called genetically as <100> orientation.

In the transistor according to the present embodiment, the boundary between the buried acoustic reflection layer and the source region or the drain region is not parallel to the gate electrode, but the boundary has a suitable angle to the gate electrode. In other words, the acoustic reflection layer is disposed so as to be aslant to length direction of the gate electrode. It is desirable that this angle is 45° to the direction in which the gate electrode is disposed. This is because phonons scattered at the interface between the silicon crystal and the buried acoustic reflection layer change in travel direction by 90° on the average and travel in the [100] direction again in which the phonons are hard to be scattered and consequently the thermal energy can spread from the MOS transistor more rapidly.

At the same time, the source region and the drain region are disposed so as to be parallel to the direction in which the gate electrode is disposed, and the source region and the drain region are disposed so as to extend in mutually opposite directions. Owing to such a configuration, a part of acoustic phonons generated in the channel is scattered by the buried acoustic reflection layer and changed in travel direction. Therefore, the partial acoustic phonons do not proceed toward an adjacent transistor, but are guided in a direction which is parallel to the direction in which the gate electrode is disposed, i.e., in a direction in which the transistor is not disposed. As a result, the thermal energy can be propagated to the outside of the transistor efficiently and the temperature rise can be suppressed.

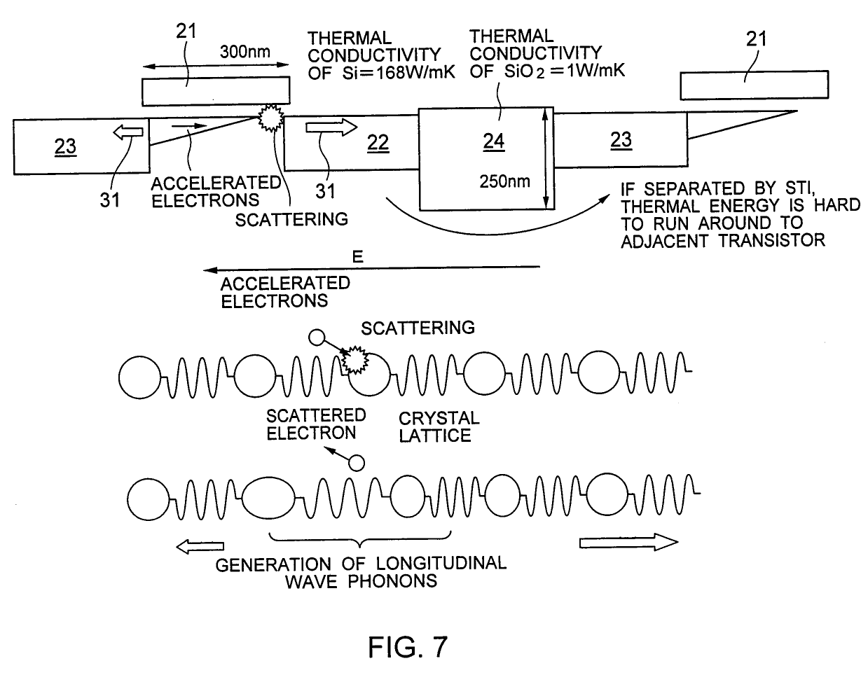

FIG. 7 is a schematic diagram showing scattering of electrons by a crystal lattice and a generation mechanism of longitudinal wave phonons. Electrons which are conducted in the channel are accelerated by an electric field applied between the drain and source, and obtain the highest kinetic energy near the drain. Since the gate electrode is formed in parallel to [100] of the silicon crystal, electrons also have kinetic energy in the [100] direction. If the electric field is weak, i.e., in the linear region of the transistor, electrons are elastically scattered mainly by the crystal lattice, and longitudinal wave acoustic phonons are generated. If the electric field is strong, i.e., in the saturation region of the transistor, electrons having high energy gradually increase, and optical phonons are generated by nonelastic scattering. An optical phonon having high energy collapse into two acoustic phonons via in harmony of vibration potential.

Since the Debye temperature of the silicon crystal is as high as 640 K, the probability of having energy sufficient to cause the umclapp scattering is comparatively low at the room temperature. Since the longitudinal wave acoustic phonons travel in the [100] direction, the longitudinal wave acoustic phonons are longer in mean free path and hard to be scattered as compared with waves which travel in other orientations. The wave which has thus traveled at a velocity which is nearly equal to the acoustic velocity strikes against the buried acoustic reflection layer formed in the substrate between transistors, and the wave is reflected.

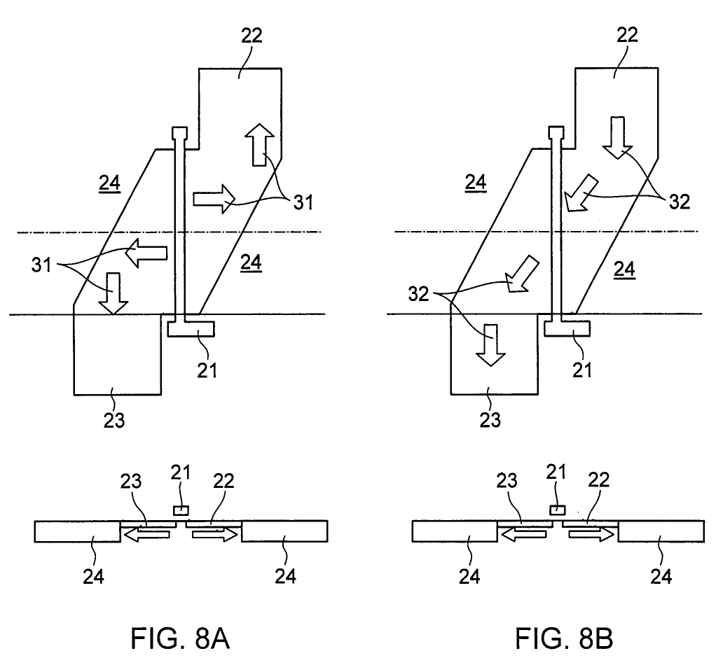

FIGS. 8A and 8B show a direction 31 in which thermal energy flows and a direction 32 in which a current flows, in the MOS transistor formed according to the present embodiment. Since the buried acoustic reflection layer is disposed at some angle to an angle at which the gate electrode is disposed, preferably disposed in a direction of 45°, a wave 31 of scattered acoustic phonons is reflected into a direction of 90° to the incidence direction. In the MOS transistor according to the present embodiment, therefore, the generated thermal energy can efficiently spread to the outside of the transistor. On the other hand, since the current flows from the drain to the source through the channel as shown in FIG. 8B, an additional effect that the current density becomes more uniform through the circuit path is anticipated.

Thus, according to the present embodiment, in a high frequency power amplifier including a plurality of transistors having sources, drains and gates formed on the same semiconductor substrate, which are respectively connected in parallel (connected in common), acoustic reflection layers buried in the substrate between adjacent transistors is provided, the buried acoustic reflection layers are disposed at some angle to the gate electrodes, and the source regions and the drain regions are disposed so as to be parallel to the gate electrode direction and extend in directions which are opposite to each other.

In the transistor according to the present embodiment, the gate electrode is divided into a plurality of pieces and the pieces are arranged on the same semiconductor substrate, in the same way as the conventional MOS transistor having the multi-finger configuration. In the conventional typical multi-finger configuration, however, adjacent regions between gate fingers share either the source region or the drain region and are separated only by the space thereof. On the other hand, the present embodiment differs in that the buried acoustic reflection layer is provided between adjacent transistors. Such a buried acoustic reflection layer is formed by etching the surface of the semiconductor substrate up to some depth and then burying an insulation film formed of SiO₂ which differs in acoustic impedance from the silicon substrate.

### Second Embodiment

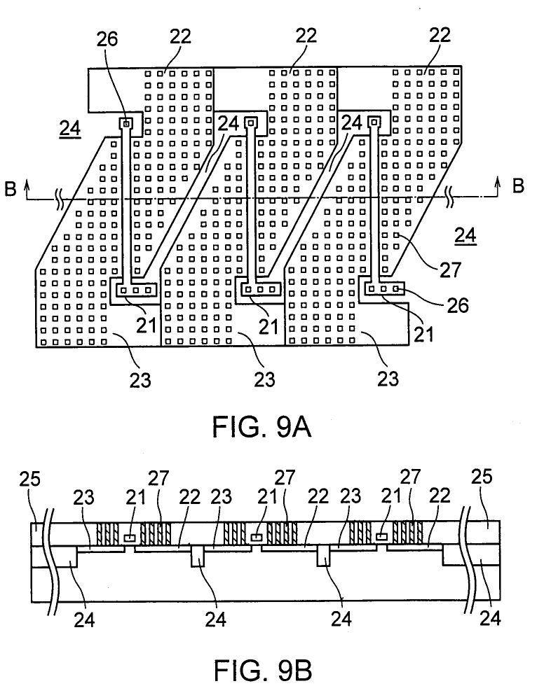

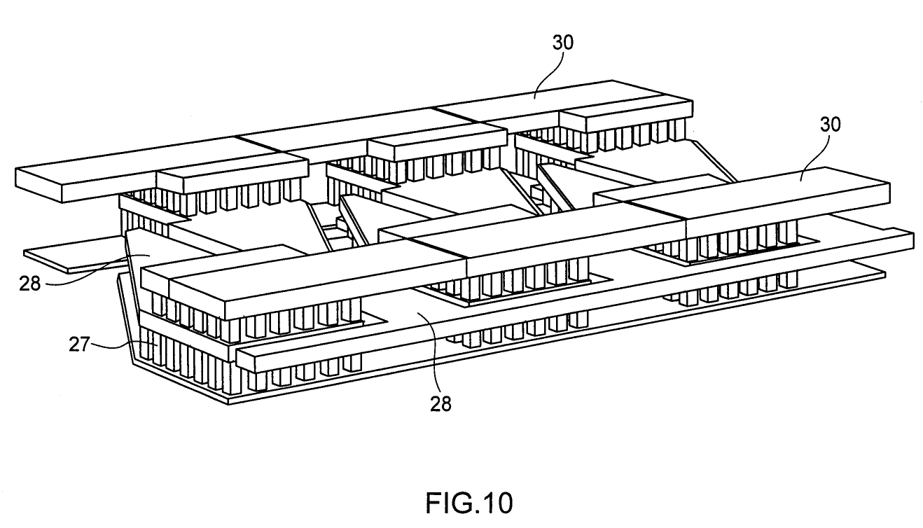

It is also possible to adopt a second embodiment as shown in FIGS. 9A, 9B and 10. FIGS. 9A and 9B show a layout of a MOS transistor for high frequency power amplifier according to the second embodiment of the present invention. FIG. 9A is a plan view, and FIG. 9B is a sectional view obtained by cutting along a cutting line B-B in FIG. 9A. FIG. 10 shows a three-dimensional layout of three-dimensional MOS transistors according to the present embodiment.

FIGS. 9A and 9B correspond to FIGS. 2A and 2B in the first embodiment. In the first embodiment, the drain regions 22 and the source regions 23 are separated between adjacent transistors. The second embodiment differs from the first embodiment in that the drain regions 22 and the source regions 23 are formed so as to be continuous to each other in regions obtained by extending the gate electrodes 21. After the structure shown in FIGS. 9A and 9B is formed, a first wiring layer 28 is provided on the interlayer insulation film 25 in the same way as FIGS. 3A and 3B in the first embodiment. In addition, the interlayer insulation film 29 is formed and the second wiring layer 30 is formed in the same way as FIGS. 4A and 4B. In this way, MOS transistors having a three-dimensional structure shown in FIG. 10 can be formed.

In such a configuration of the second embodiment, the area of the region occupied by silicon having a high thermal conductivity can be made greater as compared with the first embodiment. Accordingly, the temperature rise of the transistors can be further suppressed.

### Third Embodiment

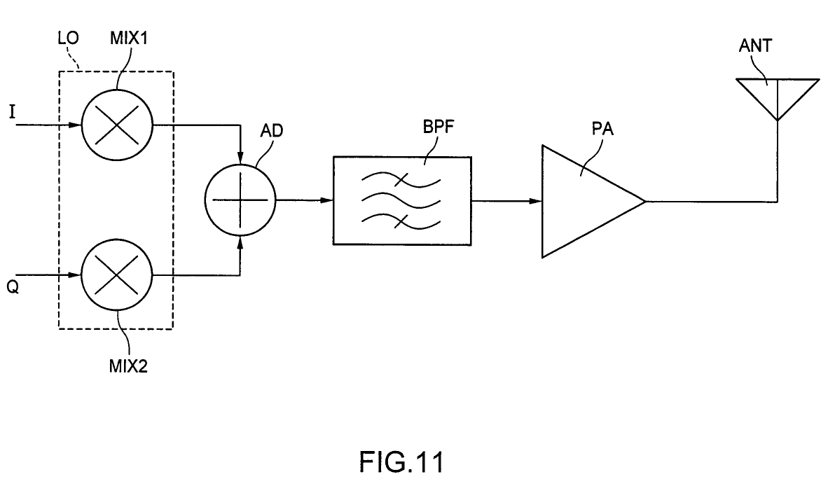

A block diagram of a transmission circuit in a wireless portable terminal according to a third embodiment of the present invention is shown in FIG. 11. The wireless portable terminal according to the present embodiment includes the high frequency power amplifier according to the first or second embodiment. This transmission circuit receives orthogonal digital signals I and Q from a baseband circuit which is not illustrated. The signals I and Q are modulated so as to become different in phase by 90 degrees in mixers MIX1 and MIX2 in a local oscillator LO. Signals obtained by the modulation are added by an adder AD, and a resultant signal is sent to a bandpass filter BPF. A signal passed through the bandpass filter BPF is amplified by a power amplifier PA. The amplified signal is radiated from an antenna ANT as an electromagnetic wave. The high frequency power amplifier according to the first or second embodiment is used as the power amplifier PA.

It is possible to obtain a wireless portable terminal which is little in output lowering at the time of operation, little in influence of thermal noise, stable in high frequency operation, and excellent in reliability, by using the high frequency power amplifier according to the first or second embodiment as heretofore described.

BY the way, the present invention is not restricted to the embodiments as they are. In the implementation stage, the present invention can be implemented with components deformed without departing from the gist of the invention. Furthermore, various inventions can be formed by suitably combining a plurality of components disclosed in the above-described embodiments. For example, some components may be removed from among all components indicated in an embodiment. In addition, components included in different embodiments may be suitably combined.

What is claimed is:

1. A high frequency power amplifier comprising:
a plurality of transistors formed in a semiconductor substrate and having gate electrodes, source regions and drain regions, the gate electrodes, source regions and drain regions being respectively connected in common; and
a plurality of acoustic reflection layers being buried in portions of the semiconductor substrate, the portions being located between adjacent transistors, the acoustic reflection layers being disposed in a direction which is oblique to a length direction of the gate electrodes.

2. The amplifier according to claim 1, wherein each of the acoustic reflection layers is disposed in a direction of 45° to the length direction of the gate electrodes.

3. The amplifier according to claim 1, wherein
the semiconductor substrate is a silicon substrate, and
each of the acoustic reflection layers is formed of an insulation film which differs from the silicon substrate in acoustic impedance.

4. The amplifier according to claim 3, wherein each of the acoustic reflection layers comprises at least one of SiO₂, SiN and Al₂O₃.

5. The amplifier according to claim 1, wherein the source regions and the drain regions are parallel to a length direction of the gate electrodes, and are disposed so as to extend in directions which are opposite to each other.

6. The amplifier according to claim 5, wherein the source regions and the drain regions of adjacent transistors are formed so that the portions extended in directions which are opposite to each other will be connected respectively.

7. The amplifier according to claim 1, wherein
the semiconductor substrate is a silicon substrate, and
the length direction of the gate electrodes is parallel to a crystal orientation <100> of the silicon substrate.

8. A wireless portable terminal comprising the high frequency power amplifier according to claim 1 in a transmission circuit.

9. The terminal according to claim 8, wherein each of the acoustic reflection layers is disposed in a direction of 45° to the length direction of the gate electrodes.

10. The terminal according to claim 8, wherein
the semiconductor substrate is a silicon substrate, and
each of the acoustic reflection layers is formed of an insulation film which differs from the silicon substrate in acoustic impedance.

11. The terminal according to claim 10, wherein each of the acoustic reflection layers comprises at least one of SiO₂, SiN and Al₂O₃.

12. The terminal according to claim 8, wherein the source regions and the drain regions are parallel to a length direction of the gate electrodes, and are disposed so as to extend in directions which are opposite to each other.

13. The terminal according to claim 12, wherein the source regions and the drain regions of adjacent transistors are formed so that the portions extended in directions which are opposite to each other will be connected respectively.

14. The terminal according to claim 8, wherein
the semiconductor substrate is a silicon substrate, and
the length direction of the gate electrodes is parallel to a crystal orientation <100> of the silicon substrate.
